(19) United States
(12) Patent Application Publication
(10) Pub. No.: US 2011/0210781 A1
(43) Pub. Date: Sep. 1, 2011

(54) LEVEL SHIFTER

(75) Inventor: Willem Groeneweg, Bremgarten (CH)

(73) Assignee: ST-ERICSSON SA., Plan-les-Ouates (CH)

(21) Appl. No.: 13/063,285

(22) PCT Filed: Sep. 9, 2009
(86) PCT No.: PCT/EP2009/061675

§ 371 Date: May 23, 2011

(30) Foreign Application Priority Data
Sep. 11, 2008 (EP) 08105304.3

(51) Int. Cl. H03L 5/00

(52) U.S. Cl. 327/333

(57) ABSTRACT

A level shifter (21) comprises a first stage (22) and a second stage (23). The first stage (22) comprises first and second inputs (34, 35) and is configured to generate a first signal (37) which indicates in a first state if either at least one of at least two first power voltages (Vdig, Vdda) provided for circuitries (38, 39) is unavailable or in a second state if each of the first power voltages (Vdig, Vdda) is available at the first and second inputs (34, 35). The second stage (23) comprises an output (51-54) and is configured to switch a second power voltage (Vbat) through to be present at the output (51-54) only if the first signal (37) is in its second state.

### FIELD OF THE INVENTION

The invention relates to a level shifter.

### BACKGROUND OF THE INVENTION

FIG. 1 ows a conventional level shifter 1 which comprises an inverter 2, two p-type transistors P1, P2 connected in a cross-coupled manner and two n-type transistors N1, N2. The sources of the transistors N1, N2 are connected to ground and the sources of the transistors P1, P2 are connected to a voltage source not explicitly shown such that a voltage having an amplitude of Vdd is present at the sources of the transistors P1, P2. The voltage Vdd is less than the breakdown voltage of the transistors N1, N2, P1, P2. The drains of transistors P1, N1 and the drains of transistors P2, N2 are connected.

A logical signal A1 and a voltage signal S1, which is a power supply voltage with magnitude Vdig, is fed to the inverter 2. The amplitude Vdd is normally larger than Vdig. The level shifter 1 converts the logical signal A1, which has also an amplitude of Vdig, to an output logical signal S2 of amplitude Vdd present at a node 3 connected to the drain of transistor P1. The inverse of the logical signal S2 is a logical signal S3 of amplitude Vdd present at a node 4 connected to the drain of transistor P2.

The level shifter 1 operates predictably if the voltage signal S1 is Vdig or at least approximately Vdig. In this case, the logical signals S2 and S3 are always in opposite states. As an example, if the logical signal A1 is logical zero, the logical signal S2 is logical zero and the logical signal S3 is logical one (Vdd). However, if the voltage signal S1 is not available and the logical signal A1 is logical zero, then both transistors N1, N2 are currentless and both nodes 3 and 4 rise to the voltage level Vdd. The logical signal S2 will be logical one instead of zero. If the logical signal S2 is used to propagate a signal to another circuit not shown in FIG. 1, it can cause malfunction of this circuit if the voltage signal S1 is not available.

### OBJECT AND SUMMARY OF THE INVENTION

It is an object of the present invention to provide an improved level shifter. The object is achieved in accordance with the invention by means of a level shifter, comprising a first stage comprising first and second inputs and configured to generate a first signal which indicates in a first state if either at least one of at least two first power voltages provided for circuitries is unavailable or in a second state if each of the first power voltages is available at the first and second inputs, and a second stage comprising an output and configured to switch a second power voltage through to be present at the output only if the first signal is in its second state. The inventive level shifter comprises the two stages, of which the first stage is configured to generate the first signal which is indicative if each of the first power voltages present at the first and second inputs is available or if at least one of them is down. The second stage is configured to only switch the second power voltage through to its output if the first signal indicates that each of the first power voltages is available. Otherwise, the second stage is operated such that the second power voltage is shut off the output.

The inventive level shifter may be meant for an electronic device, such as a mobile telephone, a PDA, a cordless telephone, an MP3 player, a CD-player, or a navigation device. The electronic device may need at least three voltage levels, for instance, one for a digital circuitry, one for an analog circuitry and one for a circuitry needing a relative strong power source, such as an output stage of the electronic circuit. Then, the second power voltage may particularly be greater than each of the first power voltages. The second power voltage may originate from a battery and is meant to power the electric circuitry needing the relative strong power source and the first power voltages may particularly have different voltage levels, for instance, around 1.2V if meant for a digital of logic circuitry and 2.5V if meant for the analog circuitry. The first power voltages may be interrupted independently or simultaneously. Then, the inventive level shifter only makes available the second power voltage particularly originating from the battery to the relevant circuitry if each of the first power voltages is available, helping to extend the battery life.

The inventive level shifter may comprise a third input configured to accept a first input signal having first and second states, wherein the first signal is in its first state if the first input signal is in its first state regardless if the first power voltages are available or unavailable. The first input signal is a “power up” signal and can be used, for instance, to turn on the level shifter when being dormant. If in its first state, the inventive level shifter shall be in its turned off state, such that the second stage is in its first state regardless of the states of the first power sources. Then the second power voltage is never switched through to the output. If the first input signal is in its second state, i.e. in its “power up” state, then the second power voltage may be present at the output depending on the availability of each of the first power voltages.

The first stage may comprise a fourth input, may be configured to compare second signals present at the first and second inputs and the first signal with a second input signal present at the fourth input, and may be configured to cause the first input signal to be in its first state if at least one of the second signals or the first input signal present at the first, second and third inputs is less than the second input signal and to cause the first signal to be in its second state if each of the second signals and the first input signal present at the first, second and third inputs is greater than the second input signal. For this embodiment, the first stage is configured to be a comparator designed to compare the signals present at the first, second, and third inputs with the signal present at the fourth input. The first input signal, i.e. the “power up” signal is in its first state if it is less than the second input signal and is in its second state if it is greater than the second input signal. The second input signal may particularly be derived from the second power voltage and may be around 0.6V.

The first stage may comprise first and second loads, a first transistor coupled to the first input and connected to the first load, a second transistor coupled to the second input and to the first load, a third transistor coupled to the third input and to the first load, and a fourth transistor coupled to the fourth input and connected to the second load, the first signal particularly being a differential signal present between the first and second loads. The first to fourth transistors may be p-type transistors and the inputs may be connected to the relevant gates. A power source, for instance, derived from the second power source, may be connected to the first to fourth transistors, the first to third transistors may be connected between the power source and the first load such that the signals at the first to third inputs control the states of the first to third transistors, and the fourth transistor may be connected between the power source and the second load such that the second input signal at the fourth input controls the states of the fourth transistor.

The first load may be formed by resistors or transistors. According to one variant of the inventive level shifter, the first load comprises fifth and sixth transistors connected in parallel and the second load comprises seventh and eighth transistors connected in parallel, wherein the sixth and eighth transistors are connected in a cross-coupled manner. The inventive level shifter may comprise a biasing circuitry powered by the second power voltage and configured to generate a bias voltage for the second stage such that the second stage operates properly.

### BRIEF DESCRIPTION OF THE DRAWINGS

The invention will be described in greater detail hereinafter, by way of non-limiting examples, with reference to the embodiments shown in the drawings.

FIG. 1 is a conventional level shift circuit,

FIG. 2 is a level shift circuit partially shown as a block diagram, and

FIG. 3 is the level shift circuit shown in greater detail.

### DESCRIPTION OF EMBODIMENTS

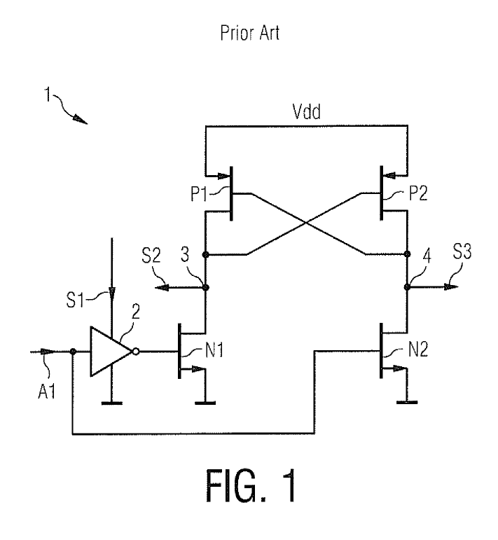

FIG. 1 has been described in the introduction.

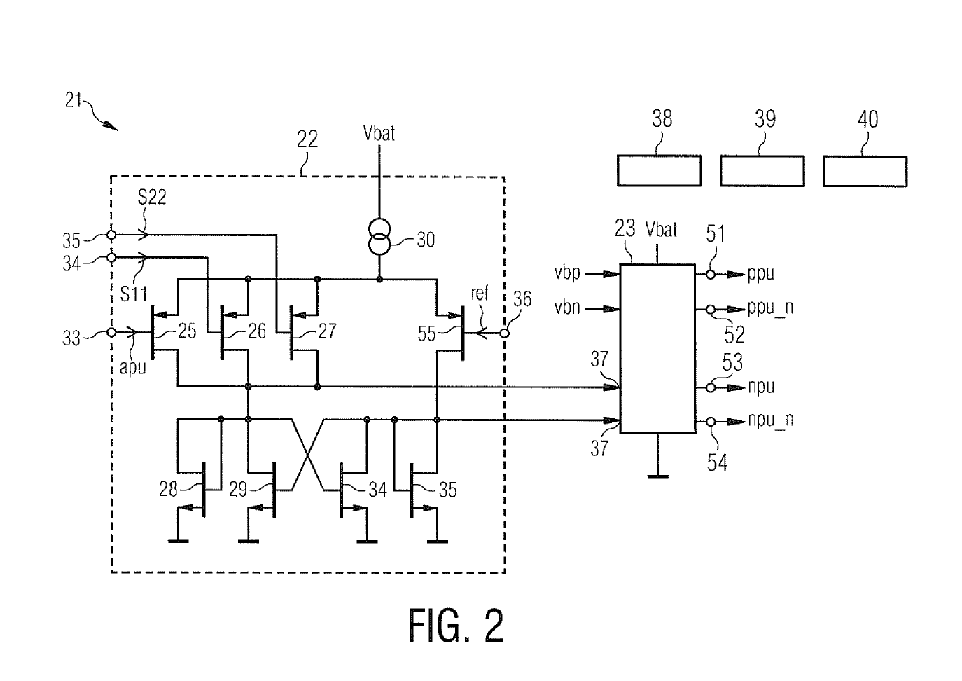

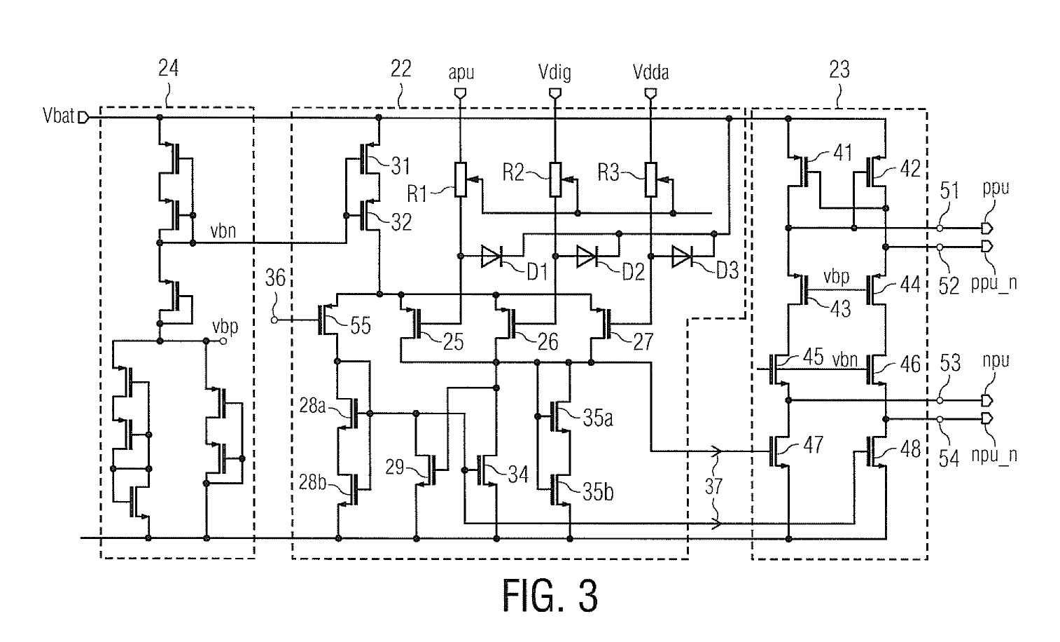

FIG. 2 shows a level shifter 21 partially as a block diagram and FIG. 3 shows the level shifter 21 in greater detail.

For the exemplary embodiment, the level shifter 21 comprises a first stage 22, a second stage 23 and a bias circuitry 24. The first stage 22 comprises p-type transistors 25, 26, 27 whose drains are connected to a first feed-forward load. The sources of transistors 25, 26, 27 are connected to a current source 30 which is powered by a voltage Vbat of approximately 2.8V to 5.0V. The current source 30 is formed by transistors 31, 32 connected in series and the voltage Vbat may be generated by a battery intended as a power source for an electric circuit 40.

The level shifter 21 comprises for the exemplary embodiment inputs 33, 34, 35, wherein input 33 is connected to the gate of transistor 25, input 34 is connected to the gate of transistor 26, and input 35 is connected to the gate of transistor 27. Input 33 is provided to accept an analog power up logical signal apu, input 34 is provided to accept an input signal S11, which is for the exemplary embodiment a voltage Vdig powering a digital circuit 38, and input 35 is provided to accept an input signal S22, which is for the exemplary embodiment a voltage Vdda powering an analog circuit 39. The value of Vdig is approximately 1.2V and the value of Vdda is approximately 2.5V.

The first stage 22 further comprises a p-type transistor 55 whose source is connected to the current source 30, whose drain is connected to a second feed forward load and whose gate is connected to a fourth input 36 of the level shifter 21. Input 36 is provided to accept a reference signal ref of approximately 0.6V. The reference signal ref is derived from the voltage Vbat generated by the battery.

For the exemplary embodiment, the first feed-forward load is comprised of two n-type transistors 28, 29 connected in parallel and the second feed-forward load is comprised of two n-type transistors 34, 35 connected in parallel. The sources of the transistors 28, 29, 34, 35 are connected to ground, the drains of the transistors 28, 29 are connected to the drains of the transistors 25, 26, 27 and the drains of the transistors 34, 35 are connected to the drain of the transistor 55. The transistors 29, 34 are connected in a cross-coupled manner such that the gate of transistor 34 is connected to the drain of transistor 29 and the gate of transistor 29 is connected to the drain of transistor 34. The transistors 28, 35 may also be comprised of two transistors 28a, 28b, 35a, 35b connected in series as shown in FIG. 3.

For the exemplary embodiment, the first stage 22 comprises resistors R1, R2, R3 and Diodes D1, D2, D3 for protecting the transistors 25, 26, 27.

For the exemplary embodiment, the first stage 22 basically functions as a comparator generating a signal 37 which is a differential signal and is present at the two feed-forward loads. During normal systems operation, the input signals S11, S22 have values of Vdig and Vdda which are both greater than the reference signal ref. Then, the analog power up signal apu controls the comparator functionality and the signal 37 is “low” if the analog power up signal apu is “low” or zero and “high” if the analog power up signal apu is “high”. Should one of the voltages Vdig or Vdda fail, then at least one of the input signals S11, S22 is less than the reference signal ref and the output signal 37 is “low” regardless of the value of the analog power up signal apu.

The signal 37 of the first stage 22 is the input signal of the second stage 23 which is comprised, for the exemplary embodiment, of p-type transistors 41-44 and n-type transistors 45-48. The sources of transistors 41, 42 are connected to the battery generating the voltage Vbat, the drain of transistor 41 is connected to the source of transistor 43 and the drain of transistor 42 is connected to the source of transistor 44. The transistors 41, 42 are connected in a cross-coupled manner such that the gate of transistor 41 is connected to the drain of transistor 42 and the gate of transistor 42 is connected to the drain of transistor 41. Transistors 45, 47 and transistors 46, 48 are connected in series, wherein the sources of transistors 47, 48 are connected to ground and the drains of transistors 45, 46 are connected to the drains of transistors 43, 44, respectively. Additionally, the signal 37 generated by the first stage 22 is fed to the gates of transistors 47, 48.

For the exemplary embodiment, the level shifter 21 comprises the bias circuitry 24 which generates bias voltages vbn, vbp intended for biasing the second stage 23. Bias voltage vbp is applied to the gates of transistors 43, 44 and bias voltage vbn is applied to the gates of transistors 47, 48.

For the exemplary embodiment, the second stage 23 comprises four outputs 51-54, wherein an output signal ppu is present at the output 51, an output signal ppu_n is present at the output 52, an output signal npu is present at the output 53, and an output signal npu_n is present at the output 54. Outputs 51, 52 have a voltage swing from half the battery voltage to the full battery voltage Vbat, i.e. a voltage swing from Vbat/2 to Vbat, and the outputs 53, 54 have a voltage swing from ground to approximately half the battery voltage Vbat, i.e. a voltage swing from ground to Vbat/2.

For the exemplary embodiment, the battery voltage is connected to the circuit 40 and the output signals ppu, ppu_n present at the outputs 51, 52 are used to set switches in the circuit 40 to turn off an electric current flow and to determine a known state, i.e. make an output of circuit 40 floating. The limited voltage swing for outputs 51, 52 is necessary for the exemplary embodiment to limit the voltage swing over the gates of transistors 41-44 to a tolerable voltage level of Vbat/2. For the exemplary embodiment, Vbat is around 5V, the maximal gate voltage swing of the switches is approximately 3V and Vbat/2 is 2.5V, which is safe.

If the level shifter 21 is in a “power down” state, i.e. if the signal 37 indicates that one of the voltages Vdig, Vdda is not available, then the output signals ppu, ppu_n set the circuit 40 in a “power down state”, turning off the electric current in circuit 40 to be zero, besides a potential small leakage current of, for instance, a few nA, by, for instance, removing the bias voltage or current and/or pulling the gates of transistors 41-44 to Vbat and the gates of transistors 45-48 to ground.

Finally, it should be noted that the aforementioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements other than those listed in any claim or the specification as a whole. The singular reference of an element does not exclude the plural reference of such elements and vice-versa. The mere fact that certain measures are recited in mutually different dependent claims does not indicate that a combination of these measures cannot be used to advantage.

1. A level shifter, comprising
a first stage (22) comprising first and second inputs (34, 35) and configured to generate a first signal (37) which indicates in a first state if either at least one of at least two first power voltages (Vdig, Vdda) provided for circuitries (38, 39) is unavailable or in a second state if each of the first power voltages (Vdig, Vdda) is available at the first and second inputs (34, 35), and
a second stage (23) comprising an output (51-54) and configured to switch a second power voltage (Vbat) through to be present at the output (51-54) only if the first signal (37) is in its second state.

2. The level shifter of claim 1, wherein the second power voltage (Vbat) is greater than each of the first power voltages (Vdig, Vdda).

3. The level shifter of claim 1, comprising a third input (33) configured to accept a first input signal (apu) having first and second states, wherein the first signal (37) is in its first state if the first input signal (apu) is in its first state regardless if the first power voltages (Vdif, Vdda) are available or unavailable.

4. The level shifter of claim 3, wherein the first stage (22) comprises a fourth input (36), is configured to compare second signals (S11, S22) present at the first and second inputs (34, 35) and the first input signal (apu) with a second input signal (ref) present at the fourth input (36), and is configured to cause the first signal (37) to be in its first state if at least one of the second signals (S11, S22) or the first input signal (apu) present at the first, second and third inputs (34, 35, 33) is less than the second input signal (ref) and to cause the first signal (37) to be in its second state if each of the second signals (S11, S22) and the first input signal (apu) present at the first, second and third inputs (34, 35, 33) is greater than the second input signal (ref).

5. The level shifter of claim 4, wherein the second input signal (ref) is derived from the second power voltage (Vbat).

6. The level shifter of claim 4, wherein the first stage (22) comprises
a first load (28, 29) and a second load (34, 35),
a first transistor (26) coupled to the first input (34) and connected to the first load (28, 29),
a second transistor (27) coupled to the second input (35) and to the first load (28, 29),
a third transistor (25) coupled to the third input (33) and to the first load (28, 29), and
a fourth transistor (55) coupled to the fourth input (36) and connected to the second load (34, 35), the first signal (37) being a differential signal present between the first and second loads (28, 29, 34, 35).

7. The level shifter of claim 6, wherein the first load comprises fifth and sixth transistors (28, 29) connected in parallel and the second load comprises seventh and eighth transistors (35, 34) connected in parallel, wherein the sixth and eighth transistors (29, 34) are connected in a cross-coupled manner, such that the gate of the sixth transistor (29) is connected to the drain of the eighth transistor (34) and the gate of the eight transistor (34) is connected to the drain of the sixth transistor (29).

8. The level shifter of claim 1, comprising a biasing circuitry (24) powered by the second power voltage (Vbat) and configured to generate a bias voltage (vbp, vbn) for the second stage (23) such that the second stage (23) operates properly.
